(19) United States
(12) Patent Application Publication
(10) Pub. No.: US 2024/0274701 A1
(43) Pub. Date: Aug. 15, 2024

(54) SEMICONDUCTOR DEVICE

(71) Applicant: SEIKO EPSON CORPORATION, Tokyo (JP)

(72) Inventor: Yohei NAKAGAWA, CHINO-SHI (JP)

(73) Assignee: SEIKO EPSON CORPORATION, Tokyo (JP)

(21) Appl. No.: 18/434,840

(22) Filed: Feb. 7, 2024

(30) Foreign Application Priority Data
Feb. 13, 2023 (JP) 2023-019999

(51) Int. Cl. H01L 29/775; H01L 29/06; H01L 29/20; H01L 29/66

(52) U.S. Cl. CPC H01L 29/775; H01L 29/0676; H01L 29/2003; H01L 29/66469

(57) ABSTRACT

A semiconductor device including a column portion and a gate electrode is provided. The column portion includes a source portion and a drain portion constituted by semiconductors having the same conductivity type, and a channel portion provided between the source portion and the drain portion and constituted by a semiconductor having a lower impurity concentration than those of the source portion and the drain portion. The gate electrode is provided at a sidewall of the column portion in the channel portion via an insulating portion, and controls the current of the channel portion. The diameter of the column portion at a first position at an end of the channel portion on the source portion side is smaller than the diameter of the column portion at a second position of the channel portion, and the second position is different from the first position.

The present application is based on, and claims priority from JP Application Serial Number 2023-019999, filed Feb. 13, 2023, the disclosure of which is hereby incorporated by reference herein in its entirety.

### BACKGROUND

### 1. Technical Field

The present disclosure relates to a semiconductor device.

### 2. Related Art

Semiconductor nanocolumns are expected to be applied to semiconductor devices such as transistors as configurations of next-generation nanodevices.

For example, JP-T-2014-503998 describes a transistor device including a nanowire and a gate surrounding the nanowire.

In the transistor device as described above, it is desired to reduce a leakage current in an off state.

### SUMMARY

In an aspect of the present disclosure, a semiconductor device includes a column portion including a source portion and a drain portion constituted by semiconductors having the same conductivity type and a channel portion provided between the source portion and the drain portion and constituted by a semiconductor having a lower impurity concentration than those of the source portion and the drain portion, and a gate electrode provided at a sidewall of the column portion in the channel portion via an insulating portion and configured to control a current of the channel portion, in which a diameter of the column portion at a first position at an end of the channel portion on a side of the source portion is smaller than a diameter of the column portion at a second position of the channel portion, the second position being different from the first position.

### BRIEF DESCRIPTION OF THE DRAWINGS

FIG. 1 is a cross-sectional view schematically illustrating a semiconductor device according to an embodiment.

FIG. 2 is a cross-sectional view schematically illustrating a column portion of the semiconductor device according to the embodiment.

FIG. 3 is a diagram for describing a relationship between an impurity concentration and a depletion layer region in the column portion.

FIG. 4 is a cross-sectional view schematically illustrating a manufacturing step of the semiconductor device according to the embodiment.

FIG. 5 is a cross-sectional view schematically illustrating a manufacturing step of the semiconductor device according to the embodiment.

FIG. 6 is a cross-sectional view schematically illustrating a manufacturing step of the semiconductor device according to the embodiment.

FIG. 7 is a cross-sectional view schematically illustrating a manufacturing step of the semiconductor device according to the embodiment.

FIG. 8 is a cross-sectional view schematically illustrating a manufacturing step of the semiconductor device according to the embodiment.

FIG. 9 is a cross-sectional view schematically illustrating a manufacturing step of the semiconductor device according to the embodiment.

FIG. 10 is a cross-sectional view schematically illustrating a column portion of a semiconductor device according to a first modified example of the embodiment.

FIG. 11 is a cross-sectional view schematically illustrating a column portion of a semiconductor device according to a second modified example of the embodiment.

### DESCRIPTION OF EMBODIMENTS

A preferred embodiment of the present disclosure will be described in detail below with reference to the drawings. Note that the embodiment described below does not unduly limit the content of the present disclosure described in the claims. In addition, not all the configurations described below are essential constituent elements of the present disclosure.

### 1. Semiconductor Device

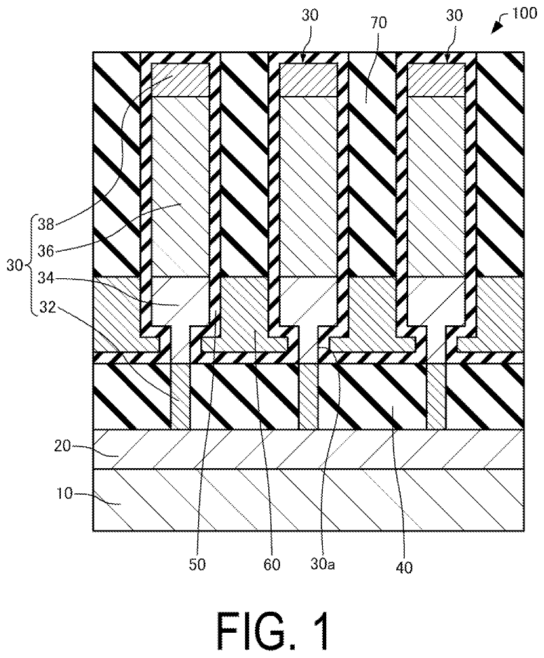

First, a semiconductor device according to an embodiment will be described with reference to the drawings. FIG. 1 is a cross-sectional view schematically illustrating a semiconductor device 100 according to the embodiment.

As illustrated in FIG. 1, the semiconductor device 100 includes, for example, a substrate 10, a buffer layer 20, a column portion 30, a first insulating layer 40, an insulating portion 50, a gate electrode 60, and a second insulating layer 70. The semiconductor device 100 is, for example, a vertical metal-oxide-semiconductor field effect transistor (MOSFET).

The substrate 10 is, for example, an Si substrate, a GaN substrate, a sapphire substrate, or an SiC substrate.

The buffer layer 20 is provided on the substrate 10. The buffer layer 20 is, for example, an n-type GaN layer doped with Si. Note that although not illustrated, a mask layer for growing the column portion 30 may be provided on the buffer layer 20. The mask layer is, for example, a titanium layer, a silicon oxide layer, a titanium oxide layer, an aluminum oxide layer, or the like.

Note that in the present specification, a description is given with a layering direction of a source portion 32 and a channel portion 34 of the column portion 30 (hereinafter, may be simply referred to as a “layering direction”) defined based on the channel portion 34. Specifically, a direction from the channel portion 34 toward a drain portion 38 of the column portion 30 is defined as “upward” and a direction from the channel portion 34 toward the source portion 32 is defined as “downward”.

The column portion 30 is provided on the buffer layer 20. The column portion 30 is provided at the substrate 10 via the buffer layer 20. The column portion 30 has a columnar shape protruding upward from the buffer layer 20. In other words, the column portion 30 protrudes upward from the substrate 10 via the buffer layer 20. The columnar portion 30 is also called, for example, a nanocolumn, a nanowire, a nanorod, or a nanopillar. The planar shape of the column portion 30 is, for example, a polygon such as a hexagon or a circle.

The diameter of the column portion 30 is, for example, 50 nm or more and 500 nm or less, and may be 100 nm or more and 300 nm or less. With the column portion 30 having a diameter of 500 nm or less, the column portion 30 of high-quality crystal can be obtained.

Note that the “diameter of the columnar portion 30” is a diameter when the planar shape of the columnar portion 30 is a circle, and is a diameter of the minimum inclusion circle when the planar shape of the columnar portion 30 is a shape other than a circle. For example, when the planar shape of the columnar portion 30 is a polygon, the diameter of the columnar portion 30 is the diameter of the smallest circle that includes the polygon therein. When the planar shape of the columnar portion 30 is an ellipse, the diameter of the columnar portion 30 is the diameter of the smallest circle that includes the ellipse therein.

For example, a plurality of the column portions 30 are provided. By including the plurality of column portions 30, the semiconductor device 100 can achieve a large current, and is thus suitably used as a power device. The plurality of columnar portions 30 are separated from each other. An interval between adjacent ones of the column portions 30 is, for example, 10 nm or more and 1 μm or less, and may be 25 nm or more and 750 nm or less. The plurality of column portions 30 are arrayed at a predetermined pitch in a predetermined direction when viewed in the layering direction. The plurality of column portions 30 are arrayed in, for example, a triangular lattice pattern or a square lattice pattern.

Note that the “pitch of the columnar portions 30” is a distance between the centers of adjacent ones of the columnar portions 30 in the predetermined direction. The “center of the columnar portion 30” is a center of a circle when the planar shape of the columnar portion 30 is the circle, and is a center of the minimum inclusion circle when the planar shape of the columnar portion 30 is a shape other than a circle. For example, when the planar shape of the columnar portion 30 is a polygon, the center of the columnar portion 30 is the center of the smallest circle that includes the polygon therein. When the planar shape of the columnar portion 30 is an ellipse, the center of the columnar portion 30 is the center of the smallest circle that includes the ellipse therein.

The column portion 30 includes, for example, the source portion 32, the channel portion 34, a drift portion 36, and the drain portion 38. The source portion 32, the channel portion 34, the drift portion 36, and the drain portion 38 are constituted by, for example, a group III nitride semiconductor, and each have a wurtzite crystal structure.

The source portion 32 is provided on the buffer layer 20. The source portion 32 is provided between the substrate 10 and the channel portion 34. The source portion 32 is provided between the buffer layer 20 and the channel portion 34. The material of the source portion 32 is, for example, n-type GaN doped with Si. The impurity concentration of the source portion 32 may be the same as the impurity concentration of the buffer layer 20.

The channel portion 34 is provided on the source portion 32. The channel portion 34 is provided between the source portion 32 and the drain portion 38. The channel portion 34 is provided between the source portion 32 and the drift portion 36. The impurity concentration of the channel portion 34 is lower than the impurity concentration of the source portion 32 and the impurity concentration of the drain portion 38. The impurity concentration of the channel portion 34 is, for example, lower than the impurity concentration of the drift portion 36. The impurity concentrations of the source portion 32, the channel portion 34, the drift portion 36, and the drain portion 38 are measured by, for example, atom probe analysis.

The material of the channel portion 34 is, for example, unintentionally doped (UID)-type GaN in which impurities are not intentionally doped, or n-type GaN. A channel is formed at the channel portion 34 by applying a predetermined voltage to the gate electrode 60. For example, an N-channel is formed at the channel portion 34.

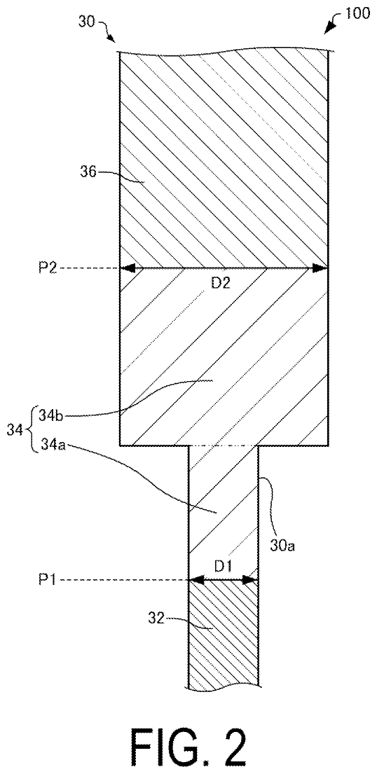

Here, FIG. 2 is a cross-sectional view schematically illustrating the vicinity of the channel portion 34 of the column portion 30.

As illustrated in FIG. 2, a diameter D1 of the column portion 30 at a first position P1 of the channel portion 34 is smaller than a diameter D2 of the column portion 30 at a second position P2 of the channel portion 34. The first position P1 is a position of an end of the channel portion 34 on the source portion 32 side. In the illustrated example, the first position P1 is a position of a boundary between the channel portion 34 and the source portion 32. The second position P2 is different from the first position P1 in the layering direction. The second position P2 is a position of an end of the channel portion 34 on the drain portion 38 side. In the illustrated example, the second position P2 is a position of a boundary between the channel portion 34 and the drift portion 36. The diameters D1 and D2 are measured by, for example, a scanning electron microscope (SEM) or a transmission electron microscope (TEM). For example, the impurity concentration at the first position P1 of the channel portion 34 is higher than the impurity concentration at the second position P2 of the channel portion 34.

As illustrated in FIG. 2, the channel portion 34 includes, for example, a first portion 34a and a second portion 34b.

The first portion 34a of the channel portion 34 is provided on the source portion 32. The first portion 34a is provided between the source portion 32 and the second portion 34b. In the illustrated example, the diameter of the column portion 30 at the first portion 34a is constant in the layering direction. The diameter of the column portion 30 at the first portion 34a is D1. In the illustrated example, the diameter D1 is the minimum width of the column portion 30 at the channel portion 34. The diameter of the column portion 30 at the first portion 34a is, for example, the same as the diameter of the column portion 30 at the source portion 32.

The second portion 34b of the channel portion 34 is provided on the first portion 34a. The second portion 34b is provided between the first portion 34a and the drift portion 36. In the illustrated example, the diameter of the column portion 30 at the second portion 34b is constant in the layering direction. The diameter of the column portion 30 at the second portion 34b is D2. In the illustrated example, the diameter D2 is the maximum width of the column portion 30 at the channel portion 34. The diameter of the column portion 30 at the first portion 34a is smaller than the diameter of the column portion 30 at the second portion 34b. The diameter of the column portion 30 at the second portion 34b is, for example, the same as the diameter of the column portion 30 at the drift portion 36.

The drift portion 36 is provided on the channel portion 34. As illustrated in FIG. 1, the drift portion 36 is provided between the channel portion 34 and the drain portion 38. The conductivity type of the drift portion 36 is, for example, the same as the conductivity type of the source portion 32 and the drain portion 38. The material of the drift portion 36 is, for example, n-type GaN doped with Si.

The impurity concentration of the drift portion 36 is lower than the impurity concentration of the source portion 32 and the impurity concentration of the drain portion 38. The drift portion 36 improves withstanding voltage of the semiconductor device 100 in an off state.

The diameter of the column portion 30 at the drift portion 36 is, for example, larger than the diameter of the column portion 30 at the source portion 32. Therefore, for example, the on-resistance can be reduced as compared with a case in which the diameter of the column portion at the drift portion is the same as the diameter of the column portion at the source portion. Furthermore, since the diameter of the column portion 30 at the source portion 32 is smaller than the diameter of the column portion 30 at the drift portion 36, for example, it is possible to reduce the possibility of dislocations caused by a difference in lattice constant between the substrate 10 and the buffer layer 20 reaching the channel portion 34.

The drain portion 38 is provided on the drift portion 36. The conductivity type of the drain portion 38 is the same as the conductivity type of the source portion 32. The material of the drain portion 38 is, for example, n-type GaN doped with Si. The diameter of the column portion 30 at the drain portion 38 is, for example, the same as the diameter of the column portion 30 at the drift portion 36.

The impurity concentration of the drain portion 38 may be the same as the impurity concentration of the source portion 32. The source portion 32, the channel portion 34, the drift portion 36, and the drain portion 38 are arranged in this order in the layering direction.

The first insulating layer 40 is provided on the buffer layer 20, for example. The first insulating layer 40 is provided between the buffer layer 20 and the gate electrode 60. The first insulating layer 40 is provided between the source portions 32 of adjacent ones of the column portions 30. The first insulating layer 40 surrounds the source portion 32 when viewed in the layering direction. The first insulating layer 40 is, for example, a spin-on-glass (SOG) layer.

The insulating portion 50 is provided at a sidewall 30a of the column portion 30 at the channel portion 34, the drift portion 36, and the drain portion 38. The insulating portion 50 is further provided at the upper surface of the first insulating layer 40 and the upper surface of the column portion 30. The sidewall 30a is constituted by, for example, m surfaces. A step is formed at the sidewall 30a due to a difference in the diameter between the first portion 34a and the second portion 34b of the channel portion 34. In the illustrated example, in the layering direction, a position of a boundary between the insulating portion 50 and the first insulating layer 40 is the same as the position of the boundary between the channel portion 34 and the source portion 32. The insulating portion 50 is provided between the channel portion 34 and the gate electrode 60. A portion of the insulating portion 50 provided between the channel portion 34 and the gate electrode 60 serves as a gate insulating layer. The insulating portion 50 surrounds the channel portion 34 when viewed in the layering direction. The material of the insulating layer 50 is, for example, silicon oxide.

The gate electrode 60 is provided at the sidewall 30a of the column portion 30 in the channel portion 34 via the insulating portions 50. The gate electrode 60 is provided between the channel portions 34 of adjacent ones of the column portions 30. In the illustrated example, a position of a boundary between the gate electrode 60 and the second insulating layer 70 is the same as the position of the boundary between the channel portion 34 and the drift portion 36 in the layering direction. The gate electrode 60 surrounds the column portion 30 and the insulating portion 50 when viewed in the layering direction. The semiconductor device 100 has a gate all around (GAA) structure. The material of the gate electrode 60 is, for example, polysilicon doped with impurities such as phosphorus or boron, or a metal. The gate electrode 60 controls the current of the channel portion 34.

The second insulating layer 70 is provided on the gate electrode 60. The second insulating layer 70 is provided between the drift portions 36 and between the drain portions 38 of adjacent ones of the column portions 30. The second insulating layer 70 surrounds the drift portion 36 and the drain portion 38 when viewed in the layering direction. The material of the second insulating layer 70 is, for example, the same as that of the first insulating layer 40.

The semiconductor device 100 is, for example, a power device used for controlling or supplying electric energy. The semiconductor device 100 is applied to, for example, an inverter, a charger, a booster, a step-down transformer, a direct current (DC)/DC converter, an electric aircraft, an electric vehicle, and the like.

The semiconductor device 100 has, for example, the following operations and effects.

The semiconductor device 100 includes the column portion 30 that includes: the source portion 32 and the drain portion 38 constituted by semiconductors having the same conductivity type, and the channel portion 34 provided between the source portion 32 and the drain portion 38 and constituted by a semiconductor having an impurity concentration lower than those of the source portion 32 and the drain portion 38. Further, the semiconductor device 100 includes the gate electrode 60 that is provided at the sidewall 30a of the column portion 30 in the channel portions 34 via the insulating portions 50 and that controls the current of the channel portion 34. The diameter D1 of the column portion 30 at the first position P1 of the end of the channel portion 34 on the source portion 32 side is smaller than the diameter D2 of the column portion 30 at the second position P2 different from the first position P1 of the channel portion 34.

Thus, in the semiconductor device 100, it is easy to completely deplete the channel portion 34 at the first position P1 at which the impurity concentration is higher than that at the second position P2.

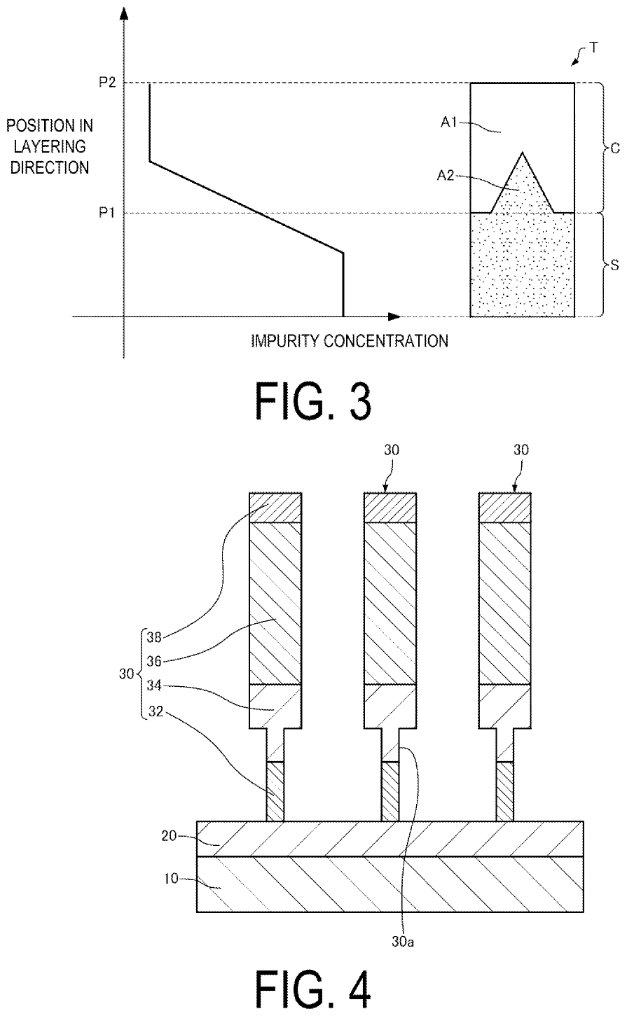

Here, FIG. 3 is a diagram for describing a relationship between the impurity concentration and a depletion layer region A1 in a column portion T.

As illustrated in FIG. 3, the first position P1 at an end of a channel portion C on a source portion S side has a high impurity concentration. This is because the impurities in the source region S diffuse into the channel region C due to heat or the like. Typically, a drift portion having an impurity concentration lower than that of a drain portion is provided between the channel portion C and the drain portion. Thus, the amount of impurities diffused from the drain portion and the drift portion into the channel portion C is smaller than the amount of impurities diffused from the source portion S into the channel portion C. Therefore, the impurity concentration at the first position P1 at the end of the channel portion C on the source portion S side is higher than the impurity concentration at the second position P2 at the end of the channel portion C on the drain portion side.

When the impurities of the source portion S are diffused into the channel portion C, the center of the column portion T is not depleted and becomes a conductive region A2 on the source portion S side of the channel portion C, as illustrated in FIG. 3. The higher the impurity concentration, the wider the width of the conductive region A2 and the narrower the width of the depletion layer region A1. Therefore, a leakage current in the off state increases.

With respect to the problem described above, in the semiconductor device 100, the diameter D1 of the column portion 30 at the first position P1 at the end of the channel portion 34 on the source portion 32 side is smaller than the diameter D2 of the column portion 30 at the second position P2 different from the first position P1 of the channel portion 34. Thus, even if the impurity concentration at the first position P1 is high, it is easy to completely deplete the channel portion 34 at the first position P1. Therefore, the leakage current in the off state can be reduced. For example, the semiconductor device 100 can realize a normally-off state in which the semiconductor device 100 is turned off at a gate voltage of 0V.

Further, in the semiconductor device 100, since the diameter D2 is larger than the diameter D1, the current in an on state can be increased.

In the semiconductor device 100, the second position P2 is the position at the end of the channel portion 34 on the drain portion 38 side. Therefore, in the semiconductor device 100, it is possible to increase the diameter of the column portion 30 at the end of the channel portion 34 on the drain portion 38 side at which the impurities are less likely to be diffused. In this way, the current in the on state can be increased.

In the semiconductor device 100, the column portion 30 includes the drift portion 36 provided between the channel portion 34 and the drain portion 38. Thus, in the semiconductor device 100, the withstanding voltage can be improved.

In the semiconductor device 100, the impurity concentration at the first position P1 of the channel portion 34 is higher than the impurity concentration at the second position P2 of the channel portion 34. In the semiconductor device 100, since the diameter D1 is smaller than the diameter D2, the channel portion 34 is easily completely depleted even at the first position P1 at which the impurity concentration is high.

In the semiconductor device 100, the channel portion 34 includes the first portion 34a and the second portion 34b, and the diameter of the column portion 30 at the first portion 34a is smaller than the diameter of the column portion 30 at the second portion 34b. Thus, in the semiconductor device 100, the diameter of the column portion 30 at the first portion 34a can be set to D1, and the diameter of the column portion 30 at the second portion 34b can be set to D2.

In the semiconductor device 100, the gate electrode 60 surrounds the channel portion 34. Thus, in the semiconductor device 100, the channel portion 34 is easily completely depleted.

The semiconductor device 100 includes the substrate 10, the column portion 30 is provided at the substrate 10, and the source portion 32 is provided between the substrate 10 and the channel portion 34. Therefore, in the semiconductor device 100, since the channel portion 34 is grown after growing the source portion 32, the impurities remain on the upper surface of the source portion 32. As a result, the impurity concentration of the channel portion 34 at the first position P1 becomes high. However, since the diameter D1 is smaller than the diameter D2 in the semiconductor device 100, the channel portion 34 is easily completely depleted even at the first position P1 at which the impurity concentration is high.

### 2. Manufacturing Method of Semiconductor Device

Next, a manufacturing method of the semiconductor device 100 according to the embodiment will be described with reference to the drawings. FIGS. 4 to 9 are cross-sectional views schematically illustrating manufacturing steps of the semiconductor device 100 according to the embodiment.

As illustrated in FIG. 4, the buffer layer 20 is epitaxially grown on the substrate 10. Examples of the epitaxial growth method include a metal organic chemical vapor deposition (MOCVD) method and a molecular beam epitaxy (MBE) method.

Subsequently, a mask layer (not illustrated) is formed on the buffer layer 20. Subsequently, the source portion 32, the channel portion 34, the drift portion 36, and the drain portion 38 are epitaxially grown in this order on the buffer layer 20 using the mask layer as a mask. Examples of the epitaxial growth method include an MOCVD method and an MBE method. With this step, the plurality of column portions 30 can be formed. By adjusting film forming conditions such as a film forming temperature and a film forming speed of the epitaxial growth, the diameter of the column portion 30 such as the diameter D1 and the diameter D2 can be controlled.

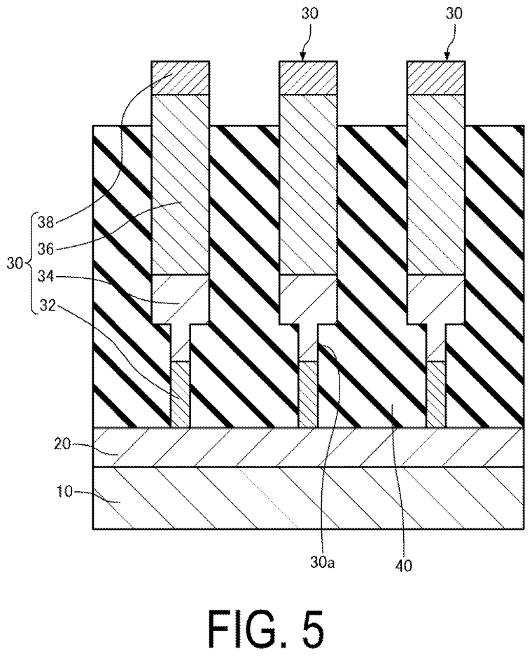

As illustrated in FIG. 5, the first insulating layer 40 is formed between adjacent ones of the column portions 30. In the illustrated example, the first insulating layer 40 is formed between the source portions 32, between the channel portions 34, and between the drift portions 36 of the adjacent ones of the column portions 30. The first insulating layer 40 is formed by an SOG method, an atomic layer deposition (ALD) method, a chemical vapor deposition (CVD) method, or the like, for example.

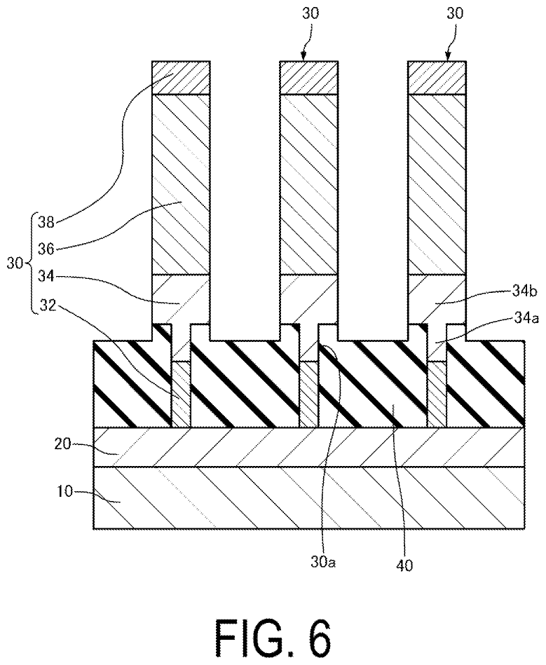

As illustrated in FIG. 6, the first insulating layer 40 is etched to remove the first insulating layer 40 between the drift portions 36 of the adjacent ones of the column portions 30 and the first insulating layer 40 at the second portion 34b of the channel portion 34. As the etching, for example, dry etching is used. In this way, the processing time of etching can be shortened as compared with a case in which wet etching is used as the etching. Furthermore, the reproducibility of the shape of the etched first insulating layer 40 can be improved.

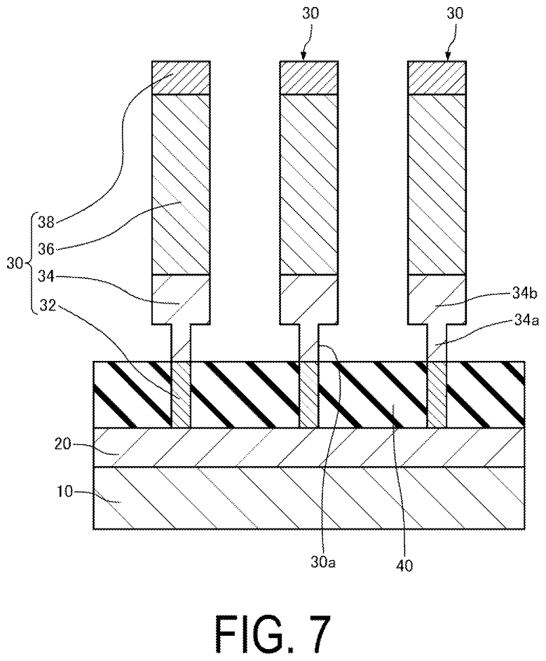

As illustrated in FIG. 7, the first insulating layer 40 is etched to remove the first insulating layer 40 between the first portions 34a of the channel portions 34 of the adjacent ones of the column portions 30. As the etching, for example, wet etching is used. In this way, damage to the first portion side 34a can be reduced as compared with a case in which dry etching is used as the etching. Since the diameter of the column portion 30 at the source portion 32 is smaller than the diameter of the column portion 30 at the second portion 34b, etching liquid is likely to be retained around the first portion 34a in the wet etching at this step. As a result, the first insulating layer 40 between the first portions 34a of the adjacent ones of the column portions 30 can be efficiently etched.

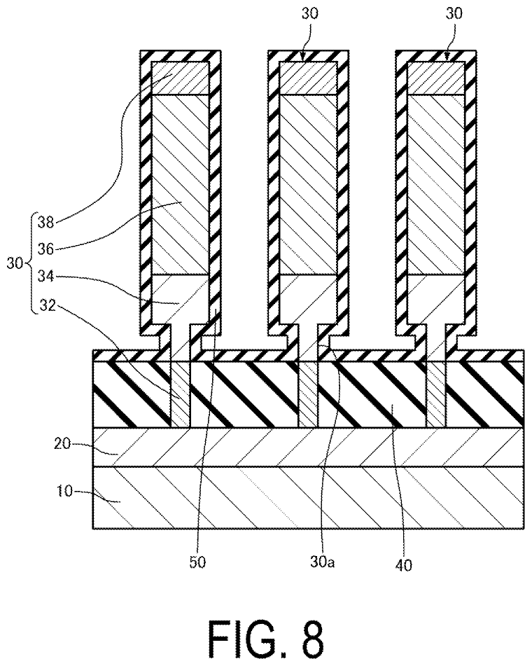

As illustrated in FIG. 8, the insulating portion 50 is formed on the first insulating layer 40 with the insulating portion 50 covering the column portion 30. The insulating layer 50 is formed by an ALD method or a CVD method, for example.

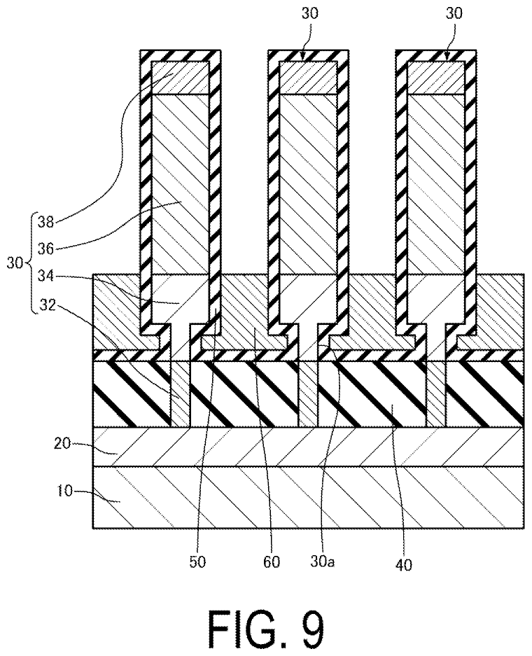

As illustrated in FIG. 9, the gate electrode 60 is formed on the first insulating layer 40 and between the channel portions 34 of the adjacent ones of the column portions 30. The gate electrode 60 is formed by an ALD method, a CVD method, or a vacuum deposition method, for example.

As illustrated in FIG. 1, the second insulating layer 70 is formed on the gate electrode 60 and between the drift portions 36 and between the drain portions 38 of the adjacent ones of the column portions 30. The second insulating layer 70 is formed by, for example, an SOG method, an ALD method, a CVD method, or the like.

The semiconductor device 100 can be manufactured by performing the steps described above.

In the above description, a bottom-up method for epitaxially growing the plurality of column portions 30 on the buffer layer 20 has been described. Note that a method of forming the column portion 30 is not particularly limited, and may be, for example, a top-down method in which a plurality of semiconductor layers are layered to form a layered body and the layered body is etched to form the plurality of column portions 30.

### 3. Modified Examples of Semiconductor Device

### 3.1. First Modified Example

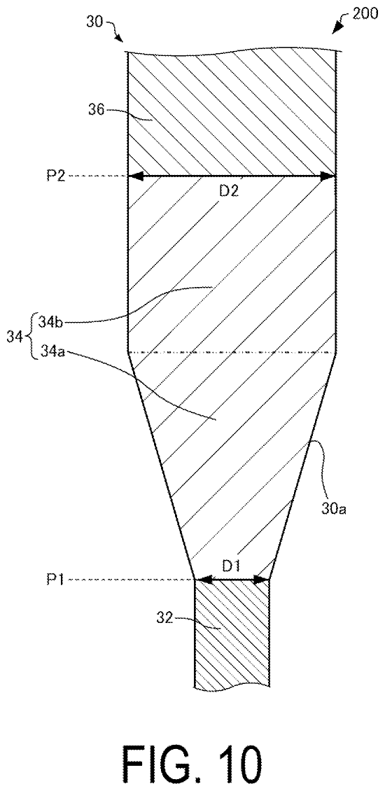

Next, a semiconductor device according to a first modified example of the embodiment will be described with reference to the drawings. FIG. 10 is a cross-sectional view schematically illustrating the column portion 30 of a semiconductor device 200 according to the first modified example of the embodiment.

In the following description, in the semiconductor device 200 according to the first modified example of the embodiment, members having the same functions as those of the constituent members of the semiconductor device 100 according to the embodiment described above will be denoted by the same reference signs and detailed description thereof will be omitted. The same applies to a semiconductor device according to a second modified example of the embodiment, which will be described later.

As illustrated in FIG. 2, in the semiconductor device 100 described above, the diameter of the first portion 34a of the channel portion 34 is constant in the layering direction.

In contrast, in the semiconductor element 200, as illustrated in FIG. 10, the diameter of the first portion 34a of the channel portion 34 gradually increases from the first position P1 toward the second position P2. In the illustrated example, the first portion 34a has a reverse tapered shape, for example.

In the semiconductor element 200, the channel portion 34 includes the first portion 34a whose diameter gradually increases from the first position P1 toward the second position P2. Therefore, in the semiconductor device 200, for example, as the impurity concentration decreases, the diameter of the channel portion 34 in the column portion 30 can be increased.

Furthermore, in the semiconductor element 200, the flatness of the sidewall 30a of the column portion 30 in the channel portion 34 is higher as compared to a case in which the diameter of the first portion of the channel portion is constant in the layering direction. As a result, it is possible to improve adhesion of the insulating portion 50 to the sidewall 30a of the column portion 30 in the channel portion 34.

### 3.2. Second Modified Example

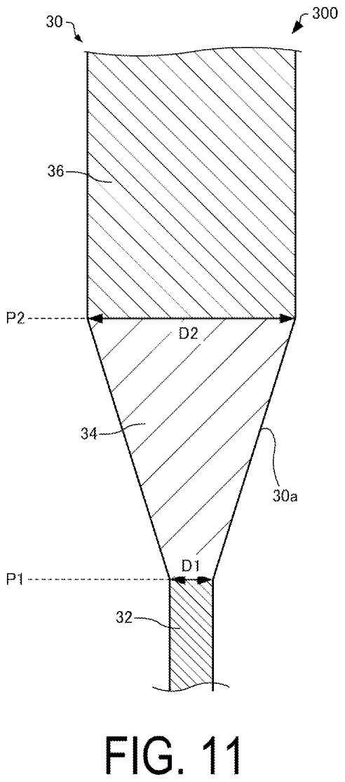

Next, the semiconductor device according to the second modified example of the embodiment will be described with reference to the drawings. FIG. 11 is a cross-sectional view schematically illustrating the column portion 30 of a semiconductor device 300 according to the second modified example of the embodiment.

In the semiconductor device 100 described above, as illustrated in FIG. 2, the channel portion 34 includes the first portion 34a and the second portion 34b, the diameter of the first portion 34a is constant in the layering direction, and the diameter of the second portion 34b is constant in the layering direction.

In contrast, in the semiconductor device 300, as illustrated in FIG. 11, the diameter of the channel portion 34 gradually increases from the first position P1 toward the second position P2. In the illustrated example, the channel portion 34 has a reverse tapered shape, for example. The channel portion 34 includes neither a first portion nor a second portion.

In the semiconductor element 300, the diameter of the channel portion 34 gradually increases from the first position P1 toward the second position P2. Therefore, in the semiconductor device 300, it is not necessary to change the film forming conditions in the channel portion 34, and the channel portion 34 can be easily formed.

The embodiment and modified examples described above are examples and are not intended as limitations. For example, each embodiment and each modified example can also be combined as appropriate.

The present disclosure includes configurations that are substantially identical to the configurations described in the embodiment, for example, configurations with identical functions, methods, and results, or with identical advantages and effects. Also, the present disclosure includes configurations obtained by replacing non-essential portions of the configurations described in the embodiment. In addition, the present disclosure includes configurations having the same operations and effects or can achieve the same advantages as those of the configurations described in the embodiment. Further, the present disclosure includes configurations obtained by adding known techniques to the configurations described in the embodiment.

The following content is derived from the embodiment and modified examples described above.

In an aspect of the present disclosure, a semiconductor device includes a column portion including a source portion and a drain portion constituted by semiconductors having the same conductivity type, and a channel portion provided between the source portion and the drain portion and constituted by a semiconductor having a lower impurity concentration than those of the source portion and the drain portion; and a gate electrode provided at a sidewall of the column portion in the channel portion via an insulating portion and configured to control a current of the channel portion. A diameter of the column portion at a first position at an end of the channel portion on a side of the source portion is smaller than a diameter of the column portion at a second position of the channel portion, the second position being different from the first position.

According to this semiconductor device, the leakage current in the off state can be reduced.

In an aspect of the semiconductor device, the second position may be a position at an end of the channel portion on a side of the drain portion.

According to this semiconductor device, the current in the on state can be increased.

In an aspect of the semiconductor device, the column portion may include a drift portion provided between the channel portion and the drain portion.

According to this semiconductor device, the withstanding voltage can be improved.

In an aspect of the semiconductor device, an impurity concentration at the first position of the channel portion may be higher than an impurity concentration at the second position of the channel portion.

According to this semiconductor device, the channel portion is easily completely depleted even at the first position at which the impurity concentration is high.

In an aspect of the semiconductor device, the channel portion may include a first portion and a second portion, and a diameter of the column portion at the first portion may be smaller than a diameter of the column portion at the second portion.

According to this semiconductor device, the diameter of the column portion at the first portion can be set to the same diameter as the diameter of the column portion at the first position, and the diameter of the column portion at the second portion can be set to the same diameter as the diameter of the column portion at the second position.

In an aspect of the semiconductor device, the channel portion may include a portion having a diameter gradually increasing from the first position toward the second position.

According to this semiconductor device, for example, as the impurity concentration decreases, the diameter of the channel portion in the column portion can be increased.

In an aspect of the semiconductor device, the gate electrode may surround the channel portion.

According to this semiconductor device, the channel portion is easily completely depleted.

In an aspect of the semiconductor device, the semiconductor device may further include a substrate, the column portion may be provided at the substrate, and the source portion may be provided between the substrate and the channel portion.

According to this semiconductor device, the channel portion is easily completely depleted even at the first position at which the impurity concentration is high.

In an aspect of the semiconductor device, the semiconductor device may be a power device.

What is claimed is:

1. A semiconductor device, comprising:
a column portion including
a source portion and a drain portion constituted by semiconductors having the same conductivity type, and
a channel portion provided between the source portion and the drain portion and constituted by a semiconductor having a lower impurity concentration than those of the source portion and the drain portion; and
a gate electrode provided at a sidewall of the column portion in the channel portion via an insulating portion and configured to control a current of the channel portion, wherein
a diameter of the column portion at a first position at an end of the channel portion on a side of the source portion is smaller than a diameter of the column portion at a second position of the channel portion, the second position being different from the first position.

2. The semiconductor device according to claim 1, wherein
the second position is a position at an end of the channel portion on a side of the drain portion.

3. The semiconductor device according to claim 1, wherein
the column portion includes a drift portion provided between the channel portion and the drain portion.

4. The semiconductor device according to claim 1, wherein
an impurity concentration at the first position of the channel portion is higher than an impurity concentration at the second position of the channel portion.

5. The semiconductor device according to claim 1, wherein
the channel portion includes a first portion and a second portion and
a diameter of the column portion at the first portion is smaller than a diameter of the column portion at the second portion.

6. The semiconductor device according to claim 1, wherein
the channel portion includes a portion having a diameter gradually increasing from the first position toward the second position.

7. The semiconductor device according to claim 1, wherein
the gate electrode surrounds the channel portion.

8. The semiconductor device according to claim 1, further comprising:
a substrate, wherein
the column portion is provided at the substrate and
the source portion is provided between the substrate and the channel portion.

9. The semiconductor device according to claim 1, wherein
the semiconductor device is a power device.
